(19) United States
(12) Patent Application Publication
(10) Pub. No.: US 2026/0013124 A1
(43) Pub. Date: Jan. 8, 2026

(54) MEMORY CELL AND METHOD FOR FABRICATING THE SAME

(71) Applicants: TAIWAN SEMICONDUCTOR MANUFACTURING COMPANY, LTD., Hsinchu (TW); NATIONAL TSING HUA UNIVERSITY, Hsinchu City (TW)

(72) Inventors: Jui-Jen WU, Hsinchu (TW); Ping-Chun WU, Taichung City (TW); Jun-Ming HSU, Hsinchu City (TW); Win-San KHWA, Taipei City (TW); Meng-Fan CHANG, Taichung City (TW)

(73) Assignees: TAIWAN SEMICONDUCTOR MANUFACTURING COMPANY, LTD., Hsinchu (TW); NATIONAL TSING HUA UNIVERSITY, Hsinchu City (TW)

(21) Appl. No.: 18/763,861

(22) Filed: Jul. 3, 2024

(51) Int. Cl. H10B 41/70; G11C 16/04; H10B 41/35

(52) U.S. Cl. CPC H10B 41/70; G11C 16/0441; H10B 41/35

(57) ABSTRACT

A memory cell includes a write access transistor, a storage transistor, a read access transistor, and a dummy transistor. The write access transistor is coupled between a storage node and a write bit line. A gate of the write access transistor is coupled to a write word line. The storage transistor is between a common node and a ground line. A gate of the storage transistor is coupled to the storage node. The read access transistor is coupled between the common node and a read bit line. A gate of the read access transistor is coupled to a read word line. A gate of the dummy transistor is coupled to the storage node, and a source/drain region of the dummy transistor is coupled to the storage node.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a memory cell according to some embodiments of the present disclosure.

FIG. 1B is a timing signal diagram of a memory cell according to some embodiments of the present disclosure.

FIG. 1C is a schematic view illustrating plural transistors of the memory cell of FIG. 1A.

FIGS. 2A-8D illustrate layouts and cross-sectional views of an integrated circuit device including plural memory cells at intermediate stages of fabrication process according to some embodiments of the present disclosure.

FIGS. 9A-9C are layouts of an integrated circuit device including plural memory cells according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

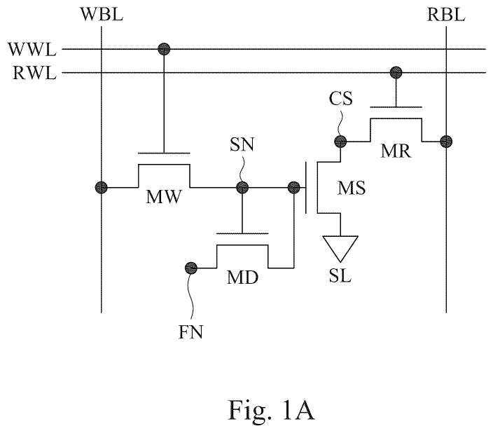

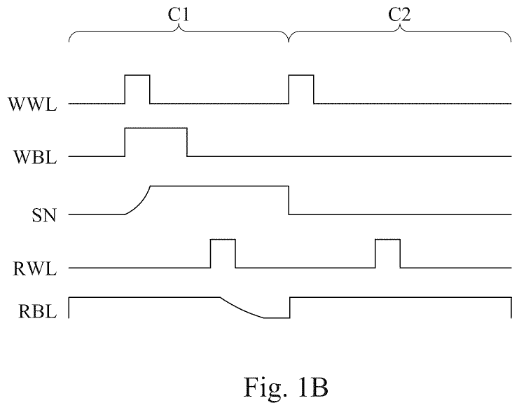

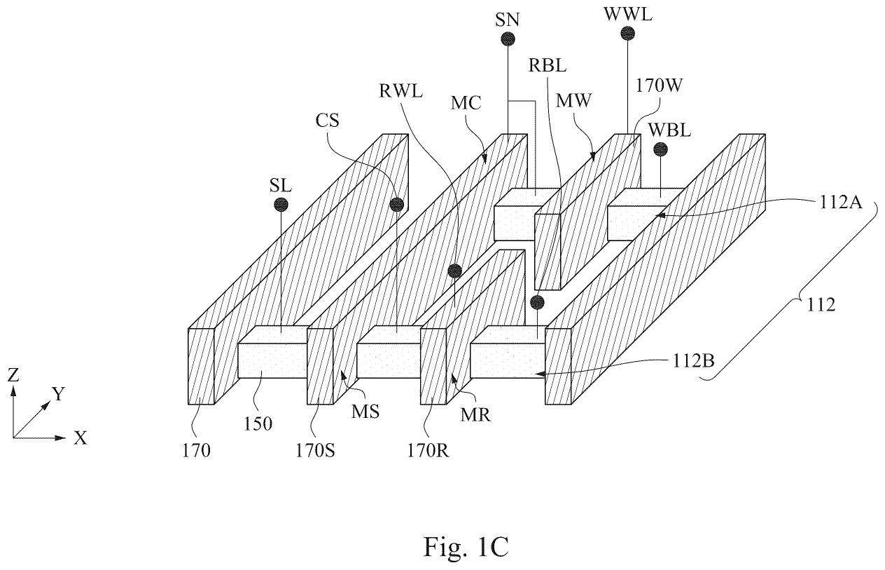

FIG. 1A is a circuit diagram of a memory cell 100 according to some embodiments of the present disclosure. The memory cell 100 includes a write access transistor MW, a read access transistor MR, a storage transistor MS, and a dummy transistor MC. The write access transistor MW is coupled between a storage node SN and a write bit line WBL, and active during a write cycle responsive to a voltage on a write word line WWL. The read access transistor MR is coupled between a read bit line RBL and a common node CS, and active during a read cycle responsive to a voltage at the read word line RWL. The storage transistor MS is coupled between the common node CS and a reference voltage line SL, and active in response to a voltage at the storage node SN. The dummy transistor MC is coupled between the storage node SN and a floating node FN, and active in response to a voltage at the storage node SN. The reference voltage line SL may be connected to a ground potential, and referred to as a ground line.

FIG. 1B is a timing signal diagram of a memory cell according to some embodiments of the present disclosure. FIG. 1B shows signal transitions of the write word line WWL, the write bit line WBL, the storage node SN, the read word line RWL, the read bit line RBL with respect to time and relationships between signal transitions. Reference is made to FIGS. 1A and 1B. The cycle C1 indicates operations for writing a selected memory cell with a data “1” and reading the memory cell. The cycle C2 indicates operations for writing a selected memory cell with a data “0” and reading the memory cell.

In the cycle C1, for writing a selected memory cell with a data “1”, a memory access cycle may begin when the read bit line RBL is precharged to a high positive voltage, and the write word line WWL transitions to a high positive voltage to cause the write access transistor MW to couple the storage node SN to the write bit line WBL. A short time after the write word line WWL goes active, the write access transistor MW couples the storage node SN to the respective write bit line WBL, and the “charge sharing” portion of the cycle begins. Shortly after the “charge sharing” has begun, sensing begins. For reading a selected memory cell, the read word line RWL transitions to a high positive voltage to cause the read access transistor MR to couple the read bit line RBL and the common node CS, a discharge current may flow from the read bit line RBL to the reference voltage line SL (e.g., ground line) when the storage node SN stores positive charges (e.g., the storage transistor MS is turned on), in which a state “1” is read.

In the cycle C2, for writing a selected memory cell with a data “0”, a memory access cycle may begin when the read bit line RBL is at a low voltage, and the write word line WWL transitions to a high positive voltage to cause the write access transistor MW to couple the storage node SN to the write bit line WBL. The read bit line RBL may discharge to the low voltage, which may be a zero or ground potential. After coupling the storage node SN to the write bit line WBL, the storage node SN may discharge and stores little charge. For reading a selected memory cell, the read word line RWL transitions to a high positive voltage to cause the read access transistor MR to couple the read bit line RBL and the common node CS, the read bit line RBL remains at the precharged positive voltage when the storage node SN stores little charges (e.g., the storage transistor MS is turned off). Thus, little or no current may flow from the read bit line RBL to the reference voltage line SL (e.g., ground line), in which a state “0” is read. In some embodiments of the present disclosure, with the configuration of the dummy transistor MC, a parasitic capacitance on the storage node SN is increased, and a retention time is improved, thereby saving energy for refresh operation.

FIG. 1C is a schematic view illustrating plural transistors of the memory cell 100 of FIG. 1A. Reference is made to FIGS. 1A and 1C. Each of the write access transistor MW, the read access transistor MR, and the storage transistor MS may include a gate structure 170 over an active region (e.g., a semiconductor fin 112) and source/drain regions 150 on opposite sides of the gate structure 170. For better illustration, the semiconductor fins 112 are labelled as semiconductor fins 112A and 112B, and the gate structures 170 are labelled as a storage gate structure 170S, a write access gate structure 170W, and a read access gate structure 170R in the drawings.

As illustrated in FIG. 1C, the read access gate structure 170R of the read access transistor MR and the storage gate structure 170S of the storage transistor MS may be over a same semiconductor fin 112B. The read access gate structure 170R of the read access transistor MR may be aligned with and separated from the write access gate structure 170W of the write access transistor MW substantially along a longitudinal direction of the read access gate structure 170R and the write access gate structure 170W (e.g., a direction Y substantially perpendicular to the direction X). In the context, the longitudinal direction of the read access gate structure 170R and the write access gate structure 170W (e.g., the direction Y) may also be referred to as gate direction. The read access gate structure 170R of the read access transistor MR may be electrically connected to the read word line RWL. The storage gate structure 170S of the storage transistor MS may be considered as (or electrically connected to) the storage node SN. The write access gate structure 170W of the write access transistor MW may be electrically connected to the write word line WWL. The read access transistor MR and the storage transistor MS may share one source/drain region 150, which is considered as (or electrically connected to) the common node CS. The other source/drain region 150 of the storage transistor MS is electrically connected to the reference voltage line SL. The other source/drain region 150 of the read access transistor MR is electrically connected to the read bit line RBL. Two source/drain regions 150 of the write access transistor MW are respectively electrically connected to the storage node SN and the write bit line WBL.

The dummy transistor MC may include a gate structure 170 (e.g., a portion of the storage gate structures 170S) over an active region (e.g., a semiconductor fin 112) and a source/drain region 150 on a side of the gate structure 170 (e.g., a portion of the storage gate structures 170S), while the other side of the gate structure 170 of the dummy transistor MC (e.g., a portion of the storage gate structures 170S) is free of a source/drain region. For example, the semiconductor fin 112A may not extend beyond a sidewall of the storage gate structures 170S, while the semiconductor fin 112B may extend beyond the sidewall of the storage gate structures 170S. In some further embodiments, the storage gate structures 170S may overlap a side of the semiconductor fin 112A, while the storage gate structures 170S may overlap a side of the semiconductor fin 112B.

In some embodiments of the present disclosure, the gate of the storage transistor MS and the gate of the dummy transistor MC may share a same gate structure 170. The gate structures 170 of the dummy transistor MC and the write access transistor MW may be over a same semiconductor fin 112. The dummy transistor MC and the write access transistor MW may share one source/drain region 150 electrically connected to the storage node SN. The dummy transistor MC can be added into a cell area (e.g., the dashed cell boundary) for improving retention time without increasing a cell region of the memory cell.

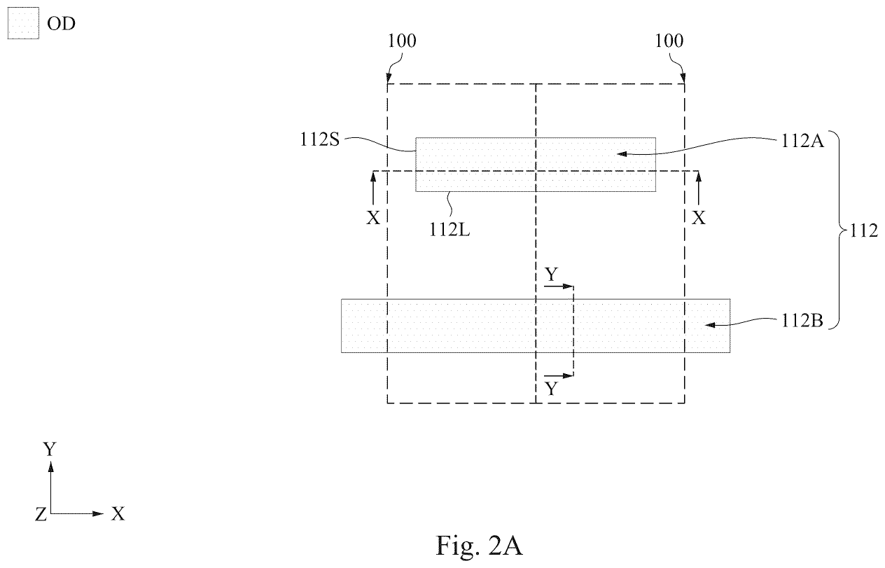

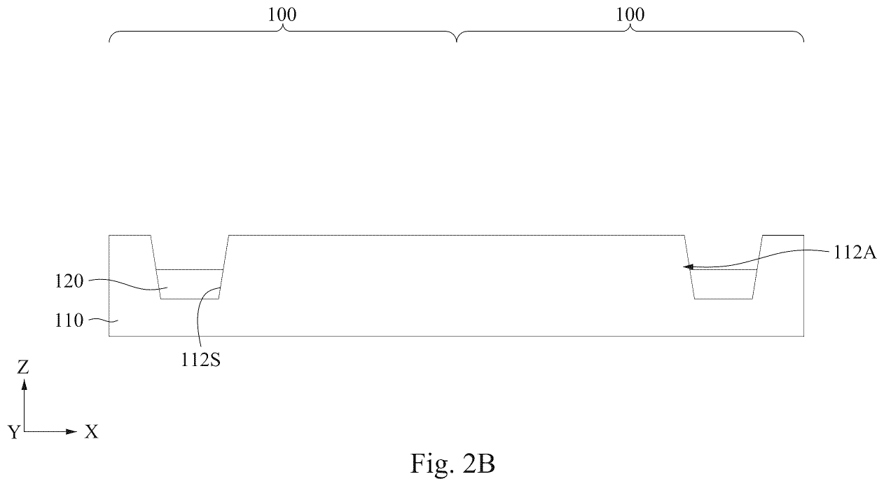

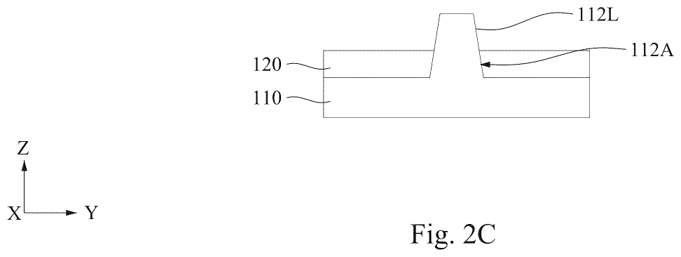

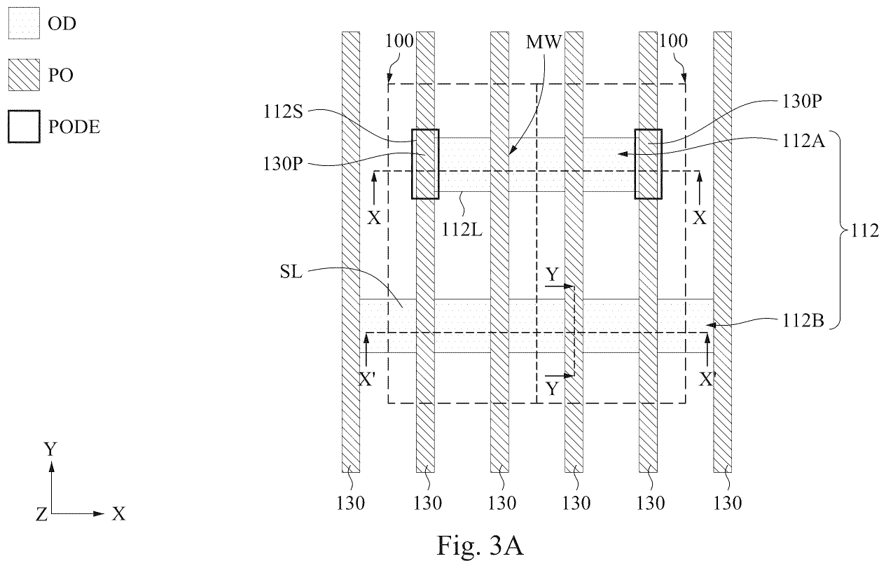

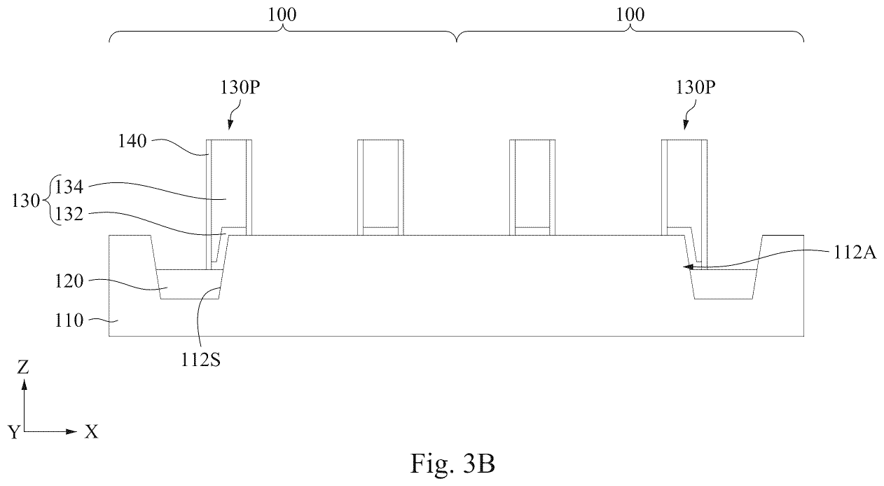

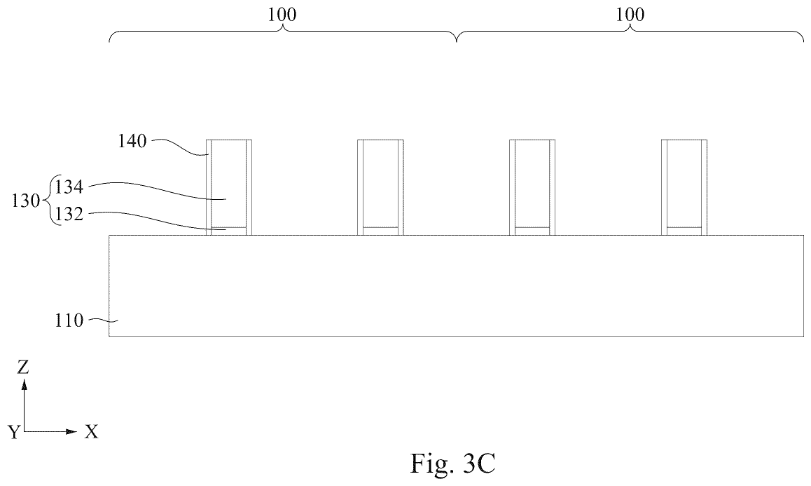

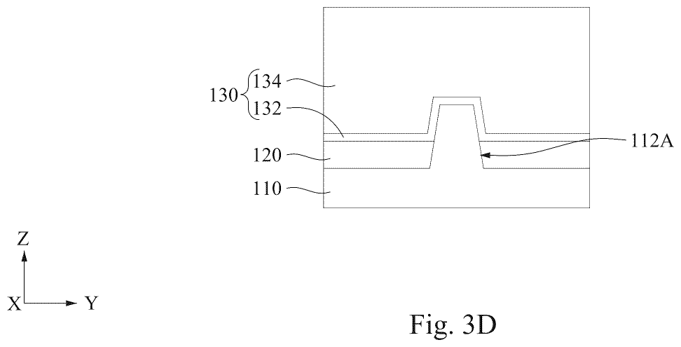

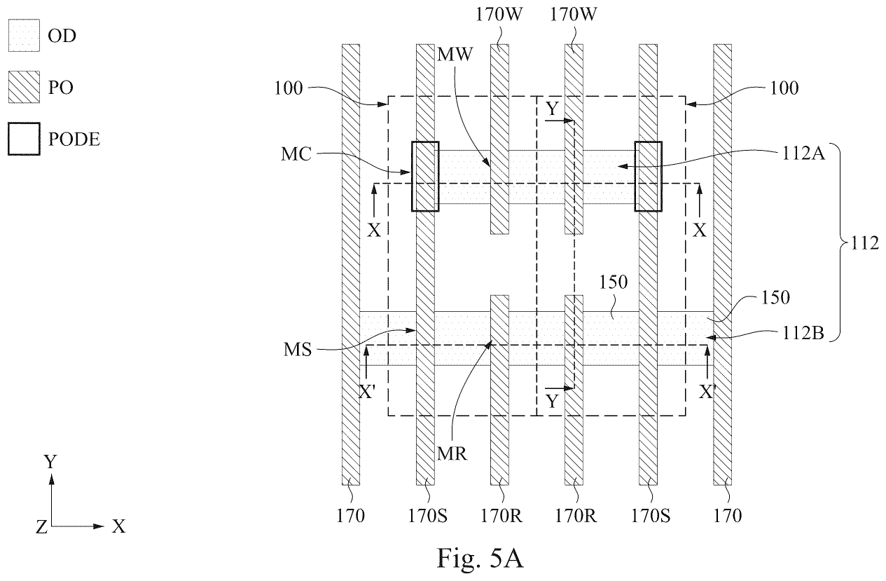

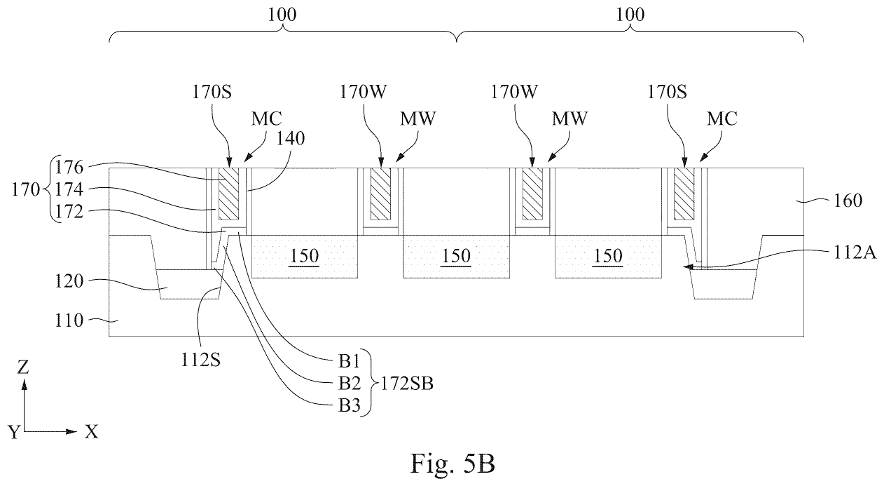

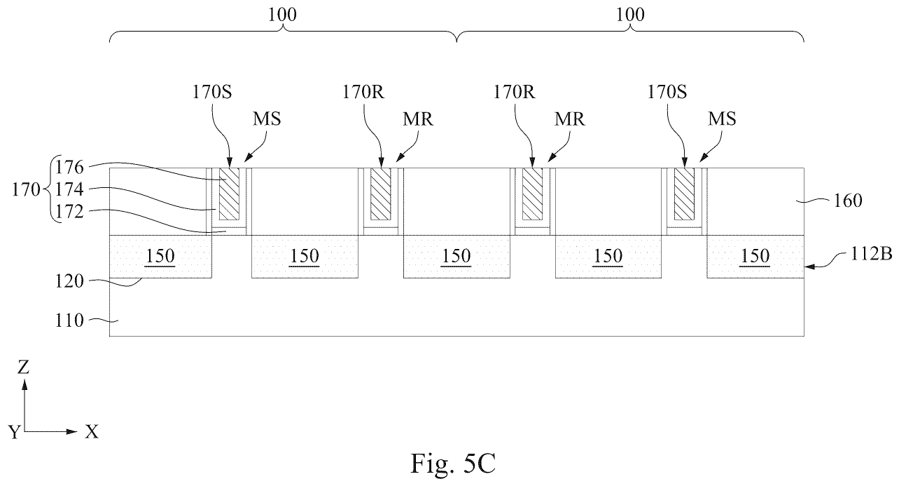

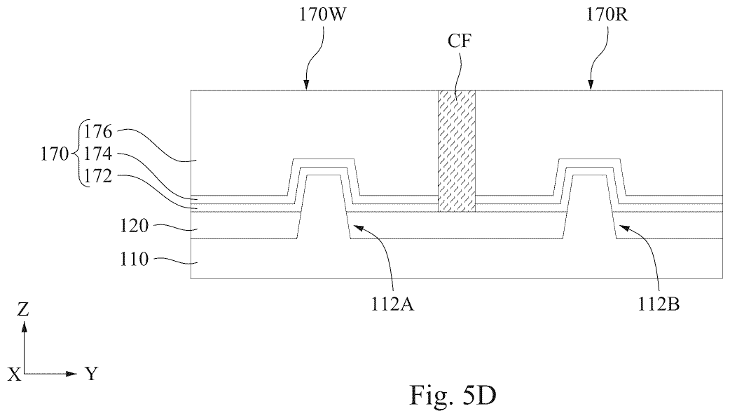

FIGS. 2A-8C illustrate layouts and cross-sectional views of an integrated circuit device including plural memory cells 100 at intermediate stages of fabrication process according to some embodiments of the present disclosure. FIGS. 2A, 3A, 4A, 5A, 6A, 7A, 8A, and 8B are layouts of the integrated circuit device including two memory cells 100 at the intermediate stages of fabrication process according to some embodiments of the present disclosure. In the layouts of FIGS. 2A, 3A,4A, 5A, 6A, 7A, 8A, and 8B, each of the memory cells 100 has a cell boundary indicated by dashed lines. FIGS. 2A, 3A,4A, 5A, 6A, 7A, 8A, and 8B may also be considered as top views of the integrated circuit device. FIGS. 2B, 3B, 4B, 5B, 6B, 7B, and 8C illustrate cross-sectional views taken along line X-X in FIGS. 2A, 3A, 4A, 5A, and 8A/8B, respectively. FIGS. 3C, 5C, 6C, 7C, and 8D illustrate cross-sectional views taken along line X′-X′ in FIGS. 3A, 5A, 6A, 7A, and 8A/8B, respectively. FIGS. 2C and 3D illustrate cross-sectional views taken along line Y-Y in FIGS. 2A and 3A, respectively. FIG. 5D illustrates a cross-sectional view taken along line Y′-Y′ in FIG. 5A. As with the other method embodiments and exemplary devices discussed herein, it is understood that parts of the integrated circuit structure may be fabricated by a CMOS technology process flow, and thus some processes are only briefly described herein. In some embodiments, the exemplary integrated circuit device includes a plurality of semiconductor devices (e.g., transistors), including PFETs, NFETs, etc., which may be interconnected.

Reference is made to FIGS. 2A-2C. A semiconductor substrate 110 is provided. The semiconductor substrate 110 may be a bulk silicon substrate. Alternatively, the semiconductor substrate 110 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 110 also include a silicon-on-insulator (SOI) substrate. SOI substrates are fabricated using separation by implantation of oxygen (SIMOX), wafer bonding, and/or other suitable methods. The semiconductor substrate 110 may also include various doped regions. The doped regions may be doped with p-type dopants, such as boron or BF₂; n-type dopants, such as phosphorus or arsenic; or combinations thereof. The doped regions may be formed directly on the substrate 110, in a P-well structure, in an N-well structure, in a dual-well structure, and/or using a raised structure. The substrate 110 may further include various active regions, such as regions configured for an n-type metal-oxide-semiconductor transistor device and regions configured for a p-type metal-oxide-semiconductor transistor device.

In some embodiments, a plurality of isolation structures 120 may be formed over the semiconductor substrate 110 for defining active regions of the substrate 110. The active regions of the substrate 110 may be referred to as oxide-defined or oxide diffusion (“OD”) regions in the layout of FIG. 2A. For example, the isolation structures 120 may act as a shallow trench isolation (STI) around the semiconductor fins 112, in which top surfaces of the isolation structures 120 are recessed to be lower than top surfaces of the semiconductor fins 112. The active regions (e.g., the semiconductor fins 112) may have long sides 112L and short sides 112S, in which the long sides 112L extend substantially along a longitudinal direction of the active region (e.g., the direction X), and the short sides 112S adjoin the long sides 112L. In some embodiments, for achieving the configuration of fin field-effect transistors (FinFETs), Lower parts of the short sides 112S and the long sides 112L of the active regions (e.g., the semiconductor fins 112) may be in contact with the isolation structure 120, while upper parts of the short sides 112S and the long sides 112L of the active regions (e.g., the semiconductor are exposed by the isolation structure 120. For better illustration, the semiconductor fins 112 are labelled as semiconductor fins 112A and 112B. The longitudinal direction of the semiconductor fins 112A may be substantially parallel with the longitudinal direction of the semiconductor fins 112B. The semiconductor fins 112B may extend beyond the short side 112S of the semiconductor fins 112A.

Reference is made to FIGS. 3A-3D. A plurality of dummy gate structures 130 are formed over the semiconductor fins 112 of the semiconductor substrate 110. In some embodiments, each of the dummy gate structures 130 includes a gate dielectric 132 and a dummy gate electrode 134 over the gate dielectric 132. The dummy gate electrode 134 may include polycrystalline-silicon (poly-Si), poly-crystalline silicon-germanium (poly-SiGe), or any suitable material. Further, the dummy gate electrode 134 may be doped poly-silicon with uniform or non-uniform doping. The gate dielectrics 132 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof.

In some embodiments, the dummy gate structures 130 may be formed by, for example, forming a stack of a gate dielectric layer, a dummy gate electrode layer, and a hard mask layer over the semiconductor substrate 110, followed by a patterning process. For example, the hard mask layer is patterned into the hard mask by suitable lithography and etching processes. In the lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. Subsequently, a pattern of the hard mask is transferred to the dummy gate electrode layer and the gate dielectric layer by any acceptable etching technique, thereby patterning the dummy gate electrode layer and the gate dielectric layer into the dummy gate electrode 134 and gate dielectric 132. In some embodiments, the etching process may include dry etching (e.g., RIE etching), wet etching, and/or other etching methods. After the patterning process, the dummy gate electrode 134 and the gate dielectric 132 covers portions of the semiconductor fins 112 of the semiconductor substrate 110, and exposes other portions of the semiconductor fins 112 of the semiconductor substrate 110.

The dummy gate structures 130 may be referred to as polysilicons (“PO”) in the layout of FIG. 3A. In the layout of FIG. 3A, polysilicon on OD edge (“PODE”) regions are some regions of dummy gate structures 130 formed on the edges of the semiconductor fins 112, which are labelled as dummy gate structures 130P. For example, the short side 112S of the semiconductor fins 112A is directly below the dummy gate structures 130. In some embodiments, PODE can be designed for preventing leakage between neighboring devices (cells). In some embodiments, PODE helps to achieve better device performance and better poly profile control. PODE can protect the ends of the semiconductor fins 112 of the cell during processing.

In some embodiments, the dummy gate structures 130 are dummy (sacrificial) gate structures that are subsequently removed. Thus, in some embodiments using a gate-last process, the dummy gate structures 130 will be replaced by the final gate structures at a subsequent processing stage of the semiconductor device. In particular, the dummy gate structures 130 may be replaced at a later processing stage by a high-k dielectric layer (HK) and metal gate electrode (MG) as discussed below.

Gate spacers 140 are formed on sidewalls of the dummy gate structures 130. Formation of the gate spacers 140 may include conformally depositing a spacer material layer on top and sidewalls of the dummy gate structures 120 over the substrate 110, and etching the spacer material layer to form the gate spacers 140. The spacer material layer may include a dielectric material such as silicon oxide, silicon nitride, silicon oxynitride, SiCN films, silicon oxycarbide, SiOCN films, and/or combinations thereof.

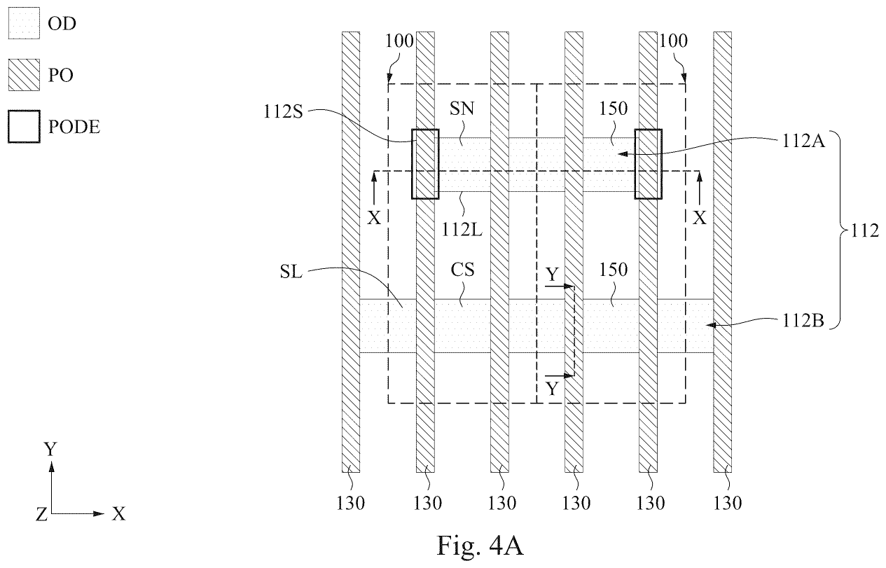

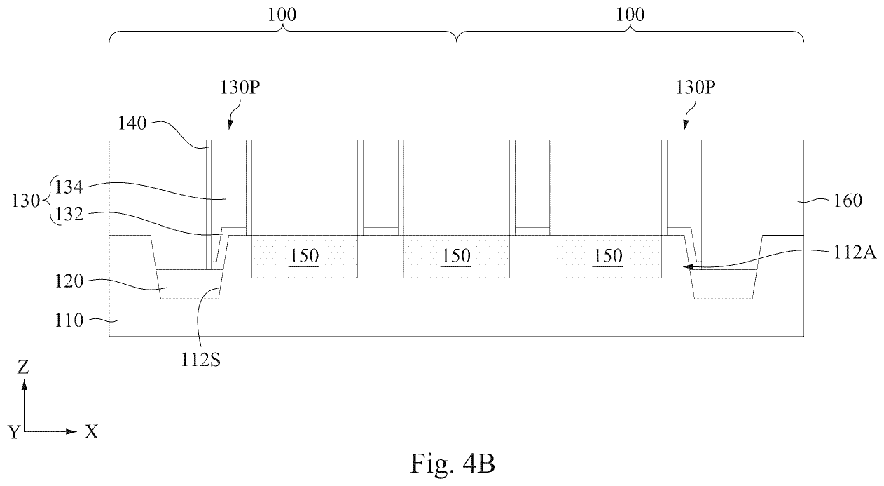

Reference is made to FIGS. 4A and 4B. After formation of the dummy gate structures 130 and the gate spacers 140, source/drain regions 150 are respectively formed in the semiconductor fins 112 of the substrate 110 and between the dummy gate structures 130. For example, one or more implantation processes is performed to dope portions of the semiconductor fins 112 of the substrate 110 exposed by the dummy gate structures 130 and the gate spacers 140, thereby forming the source/drain regions 150. Suitable dopant species may include p-type dopants, such as boron; n-type dopants, such as phosphorus or arsenic; and/or other suitable dopants including combinations thereof. In some embodiments, the source/drain regions 150 include p-type dopants such as boron for formation of p-type FETs. In other embodiments, the source/drain regions 150 include n-type dopants such as phosphorus for formation of n-type FETs. In some embodiments, the formation of the source/drain regions 150 may include optionally recessing the exposed portions of the semiconductor fins 112, epitaxially growing semiconductor materials over the portions of the semiconductor fins 112. The epitaxially growing semiconductor materials may be in-situ or ex-situ doped with the suitable dopant species. One or more annealing process (e.g., rapid thermal annealing (RTA) and/or laser annealing processes) may be performed to activate the source/drain regions 150 after the doping process.

After the formation of the source/drain regions 150, an interlayer dielectric (ILD) layer 160 is deposited over the source/drain regions 150. The ILD layer 220 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 220 may be deposited by a chemical vapor deposition (CVD) process or other suitable deposition technique. A chemical mechanical polishing (CMP) process may be performed to remove an excess portion of the ILD layer 160 until reaching the dummy gate structures 130. After the CMP process, the dummy gate electrode 134 of the dummy gate structures 130 are exposed from the ILD layer 160.

Reference is made to FIGS. 5A-5D. A high-k/metal gate replacement process is performed, in which the dummy gate structures 130 (referring to FIGS. 3A-4B) including the dummy gate structures 130P (referring to FIGS. 3A and 3B) are replaced with metal gate structures 170. The metal gate replacement process may include removing the dummy gate structures 130 (referring to FIGS. 3A-4B) to form gate trenches between the gate spacers 140, following by depositing gate material layers into the gate trenches. These gate material layers may include a gate dielectric layer 172 and a gate metal layer including a work function metal layer 174, and a fill metal 176. The gate dielectric layer 172 may include an interfacial layer formed over the semiconductor fin 112 and a high-k gate dielectric layer formed over the interfacial layer. The interfacial layer may be silicon oxide formed on exposed surfaces of semiconductor materials in the gate trenches by using, for example, thermal oxidation, chemical oxidation, wet oxidation or the like. In some embodiments, the high-k gate dielectric layer includes dielectric materials such as hafnium oxide (HfO₂), hafnium silicon oxide (HfSiO), hafnium silicon oxynitride (HfSiON), the like, or the comination thereof. The work function metal layer 174 provides a suitable work function for the metal gate structures 170. The work function metal layers may include TiN, TaN, TiAl, TiAlN, TaAl, TaAlN, TaAlC, TaCN, WNC, Co, Ni, Pt, W, or combination thereof. The fill metal 176 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. A CMP process may be performed to remove excess portions of the gate material layers external to the gate trenches. Through the processes, the write access transistor MW, the read access transistor MR, the storage transistor MS, and the dummy transistor MC are formed.

For better illustration, the gate structures 170 are labelled as a storage gate structure 170S, a write access gate structure 170W, and a read access gate structure 170R. The storage gate structure 170S can serve as gates of the storage transistor MS and gates of the dummy transistor MC. Stated differently, the storage transistor MS and the dummy transistor MC share the storage gate structure 170S. The write access gate structure 170W can serve as gates of the write access transistor MW. The read access gate structure 170R can serve as gates of the read access transistor MR. And, the write access gate structure 170W is substantially aligned with the read access gate structure 170R in the longitudinal directions of the write access gate structure 170W and the read access gate structure 170R (e.g., the direction Y) in the layout (or the top view), in which the write access gate structure 170W is spaced apart from the read access gate structure 170R. As illustrated previously, the dummy transistor MC and the write access transistor MW may share a source/drain region 150. And, the storage transistor MS and the read access transistor MR may share a source/drain region 150. With the configuration, the four devices of one memory cell 100 (e.g., the read access transistors MR, the write access transistors MW, the storage transistor MS, and the dummy transistor MC) can be disposed in a compact cell area.

The patterns of the gate structures 170 can be achieved by any suitable fabrication methods. The pattern of the metal gate structures 170 may follow the pattern of the polysilicons (“PO”) in the layout of FIG. 5A. For example, in some embodiments, the dummy gate structure 130 (referring to FIGS. 3A-4B) is first cut into two separate dummy gate structures, for example by a dielectric feature CF (also referred to as a cut-poly dielectric feature), and then respectively replaced with the metal gate structures 170, thereby forming the separate gate structures 170W and 170R. For example, prior to the high-k/metal gate replacement process, an opening is etched in the dummy gate structure 130 (referring to FIGS. 3A-4B), and one or more dielectric materials are deposited in to the opening, followed by a CMP process to remove an excess portion of the dielectric materials outside the opening. After the CMP process, a remaining portion of the dielectric materials forms the dielectric feature CF between two portions of the dummy gate structure 130 (referring to FIGS. 3A-4B), which are later respectively replaced with the gate structures 170W and 170R by the high-k/metal gate replacement process. Since the gate structures 170W and 170R are formed by replacing the two portions of a dummy gate structure, a longitudinal direction of the gate structure 170W is substantially aligned with a longitudinal direction of the gate structure 170R along the direction Y. The dielectric materials of the dielectric feature CF may include a dielectric material such as silicon oxide, silicon nitride, silicon oxynitride, SiCN, silicon oxycarbide, SiOCN, and/or combinations thereof.

In some alternative embodiments, the dummy gate structure 130 (referring to FIGS. 3A-4B) is replaced with a continuous metal gate structure first, and then a dielectric feature CF (also referred to as a cut-metal dielectric feature) is formed in the continuous metal gate structure to cut the continuous metal gate structure into the separate gate structures 170W and 170R. For example, after the high-k/metal gate replacement process, an opening is etched in the continuous metal gate structure, and one or more dielectric materials are deposited in to the opening, followed by a CMP process to remove an excess portion of the dielectric materials outside the opening. After the CMP process, a remaining portion of the dielectric materials forms the dielectric feature CF between two portions of the continuous metal gate structure, which are respectively referred to as the separate gate structures 170W and 170R. Since the gate structures 170W and 170R are formed from a continuous metal gate structure, a longitudinal direction of the gate structure 170W is substantially aligned with a longitudinal direction of the gate structure 170R along the direction Y. The dielectric materials of the dielectric feature CF may include a dielectric material such as silicon oxide, silicon nitride, silicon oxynitride, SiCN, silicon oxycarbide, SiOCN, and/or combinations thereof.

The storage gate structure 170S may inherit the shape/pattern/profile of PODE. For example, the storage gate structure 170S may overlap the short side 112S of the semiconductor fins 112A. In some embodiments, the short side 112S of the semiconductor fins 112A is directly below the storage gate structure 170S. The storage gate structure 170S may be in contact with the short side 112S of the semiconductor fins 112A. In some embodiments, when viewing along the direction Y (i.e., along the longitudinal direction of the gate structures 170), a bottom surface 170SB of the storage gate structure 170S has a first portion B1 over the semiconductor fin 112A, a second portion B2 in contact with the isolation structure 120, and a third portion B3 connecting the first portion B1 to the second portion B2 and in contact with the short side 112S of the semiconductor fins 112A.

In some embodiments of the present disclosure, the write access transistor MW, the read access transistor MR, the storage transistor MS, and the dummy transistor MC are FinFET, in which the high-k/metal gate structures 170 surround three sides of the channel (e.g., the semiconductor fins 112). The FinFET, for example, may be a complementary metal-oxide-semiconductor (CMOS) device comprising a p-type metal-oxide-semiconductor (PMOS) FinFET device and an n-type metal-oxide-semiconductor (NMOS) FinFET device. The following disclosure will continue with a FinFET example to illustrate various embodiments of the present disclosure. It is understood, however, that the application should not be limited to a particular type of device, except as specifically claimed. For example, in some embodiments, the write access transistor MW, the read access transistor MR, the storage transistor MS, and the dummy transistor MC can be planar transistors, in which the high-k/metal gate structures surround one side of the channel. In some alternative embodiments, the write access transistor MW, the read access transistor MR, the storage transistor MS, and the dummy transistor MC can be gate all around (GAA) devices or nanosheet devices having gate material disposed on at least four sides of at least one channel of the device. The channel region may be referred to as a “nanowire” or “nanosheet,” which as used herein includes channel regions of various geometries (e.g., cylindrical, bar-shaped) and various dimensions. However, one of ordinary skill would recognize that the teaching can apply to a single channel (e.g., single nanosheet) or any number of channels. One of ordinary skill may recognize other examples of semiconductor devices that may benefit from aspects of the present disclosure.

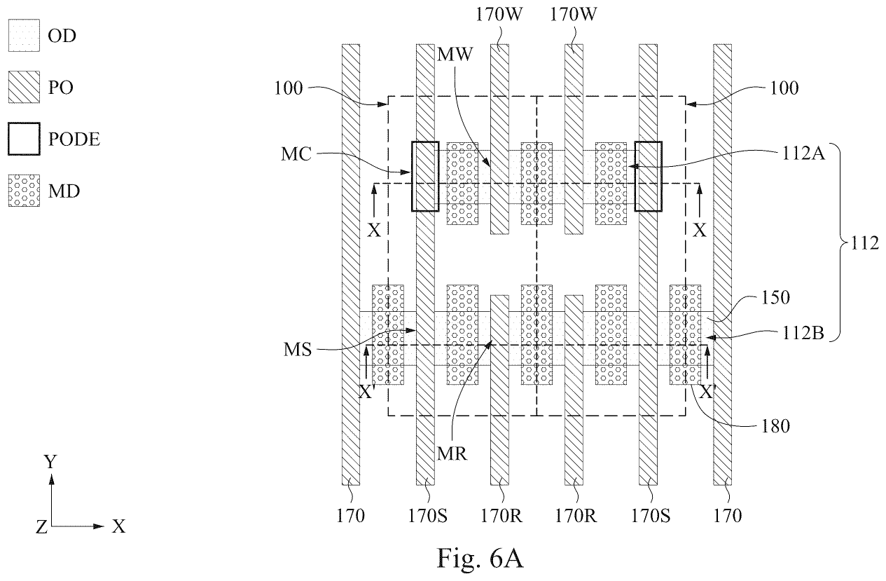

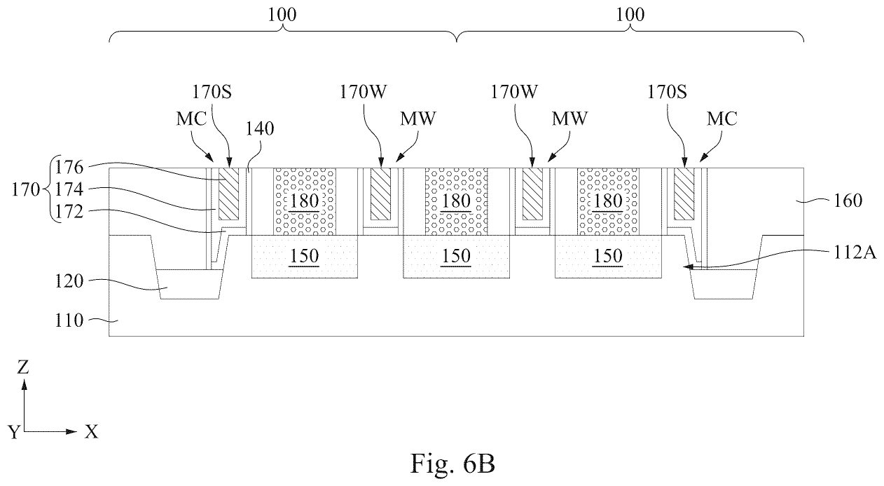

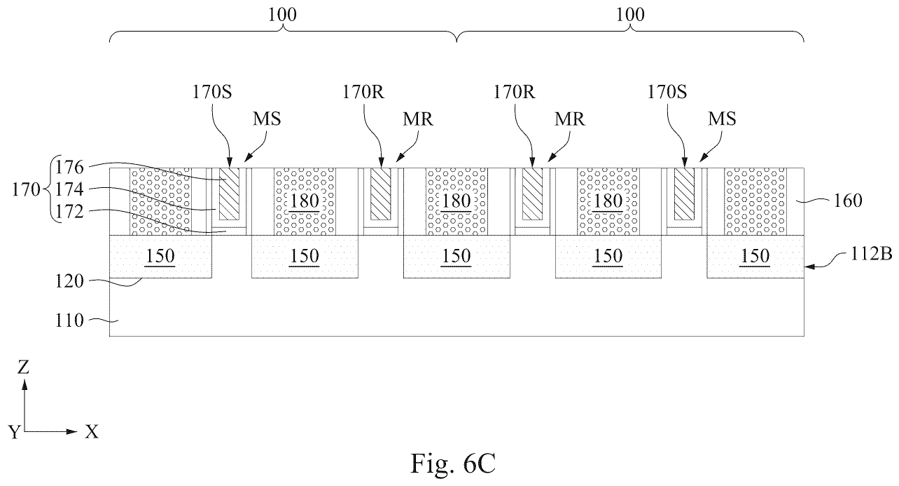

Reference is made to FIGS. 6A-6C. Source/drain contacts 180 are formed in the ILD layer 160 and over the source/drain regions 150. The source/drain contacts may be referred to as metal-to-diffusion (“MD”) in the layout of FIG. 6A. In some embodiments, source/drain contact openings are first formed through the ILD layer 160 to expose top surfaces of the source/drain regions 150 by suitable patterning process (e.g., using suitable photolithography and etching techniques). Subsequently, one or more metal materials are deposited into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., chemical vapor deposition (CVD), physical vapor deposition (PVD), atomic layer deposition (ALD), the like or combinations thereof). A CMP process can then be performed to remove excess metal materials outside the source/drain contact openings, while leaving metal materials in the source/drain contact openings to serve as the source/drain contacts 180. In some embodiments, prior to the metal deposition, metal silicide regions may be formed on exposed surfaces of the source/drain regions 150 by using a silicidation process. Silicidation may be formed by blanket depositing a metal layer over the exposed source/drain regions 150, annealing the metal layer such that the metal layer reacts with silicon in the source/drain regions 150 to form the metal silicide regions, and thereafter removing the non-reacted metal layer. In some embodiments, the metal layer used in the silicidation process includes nickel, cobalt, titanium, tantalum, platinum, tungsten, other noble metals, other refractory metals, rare carth metals or their alloys.

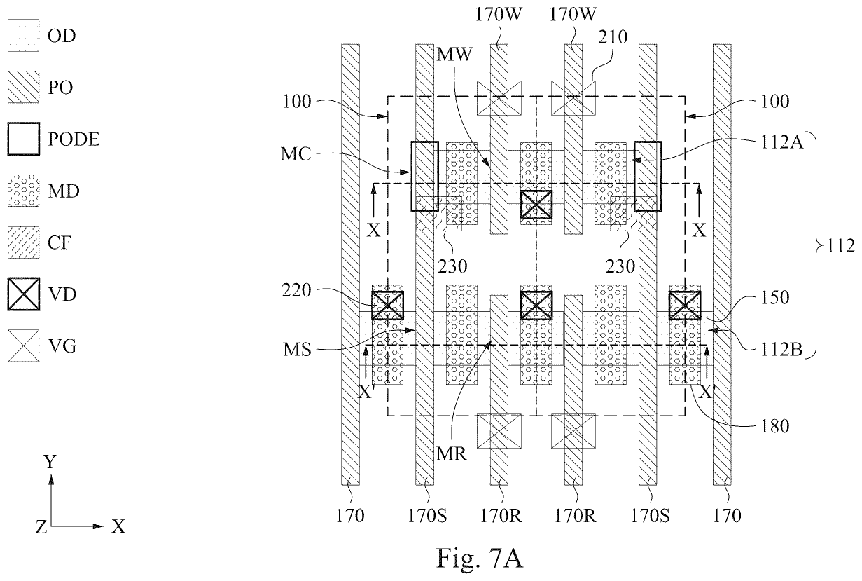

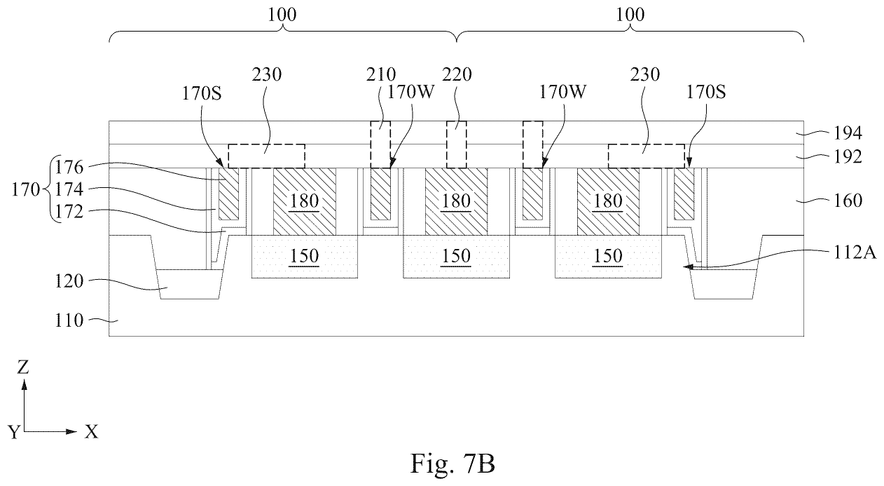

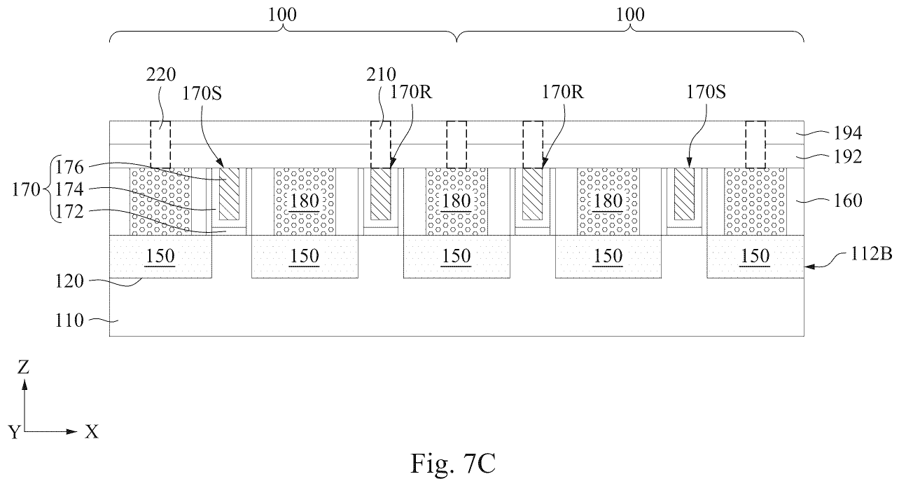

Reference is made to FIGS. 7A-7C. Gate vias 210 are formed over and in contact with the metal gate structures 170. Source/drain vias 220 are formed over and in contact with the source/drain contacts 180. Connection features 230 are formed over and in contact with the source/drain contacts 180 and the metal gate structures 170 and connect the source/drain contacts 180 to the metal gate structures 170. Formation of the connection features 230 may include depositing one or more ILD layers 192 over the structure of FIGS. 6B and 6C, etching openings in the ILD layer(s) 192, and filling the openings with one or more suitable conductive materials. One or more removal process may be performed to remove portions of the conductive materials, and remaining portions of the conductive materials in the openings may form the connection features 230. Formation of the gate vias 210 and the source/drain vias 22 may include depositing one or more ILD layers 194 over the ILD layer(s) 192, etching openings in the ILD layers 192 and 194, and filling the openings with one or more suitable conductive materials. One or more removal process may be performed to remove portions of the conductive materials, and remaining portions of the conductive materials in the openings may form the gate vias 210 and source/drain vias 220, respectively. In some embodiments, the ILD layers 192 and 194 may include low-k dielectric materials having k values, for example, lower than about 4.0 or even 2.0 disposed between such conductive features. The conductive materials may comprise metal materials such as W, Ru, Co, Cu, Ti, TiN, Ta, TaN, Mo, Ni, combinations thereof, or the like. The gate vias 210 may be denoted as “VG” in the layout in FIG. 6A, the source/drain vias 220 may be denoted as “VD” in the layout in FIG. 6A, and the connection features 230 may be denoted as “CF” in the layout in FIG. 6A. In the present embodiments, top surfaces of the connection features 230 are covered by the ILD layers 194, while top surfaces of the source/drain vias 220 and the gate vias 210 are exposed by the ILD layers 194. Stated differently, the top surfaces of the connection features 230 are lower than the top surfaces of the source/drain vias 220 and the gate vias 210.

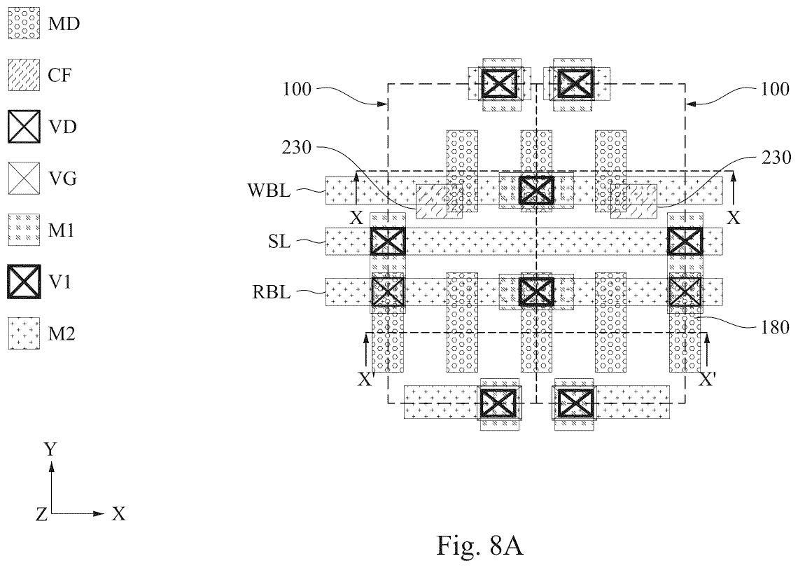

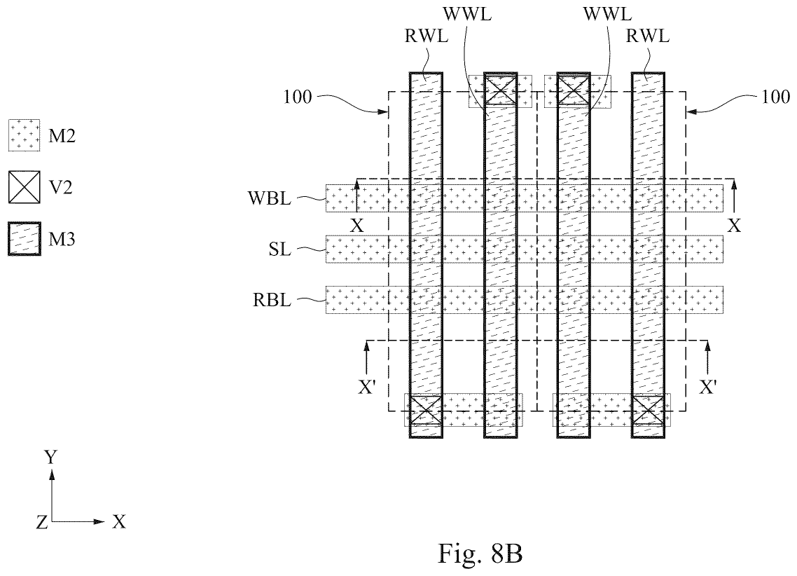

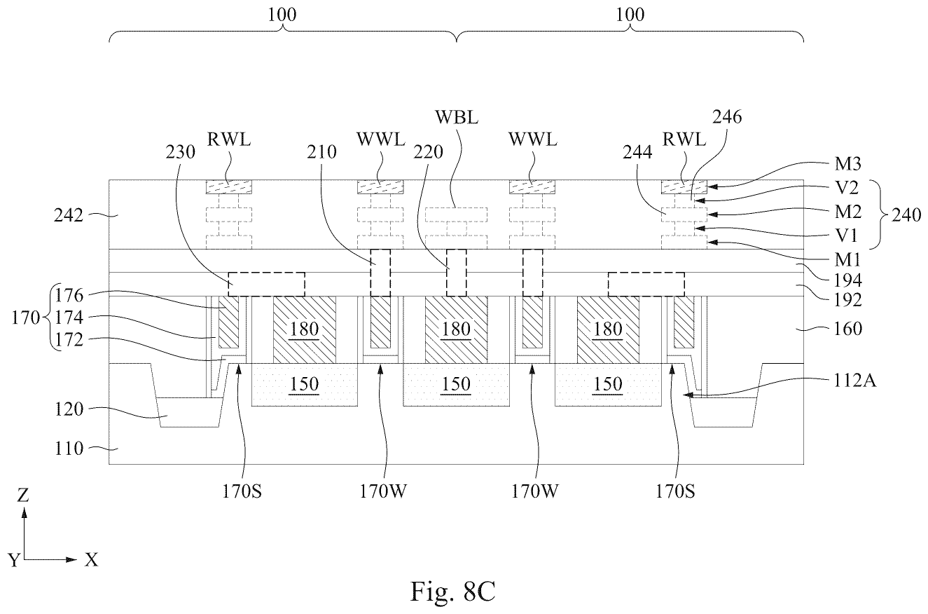

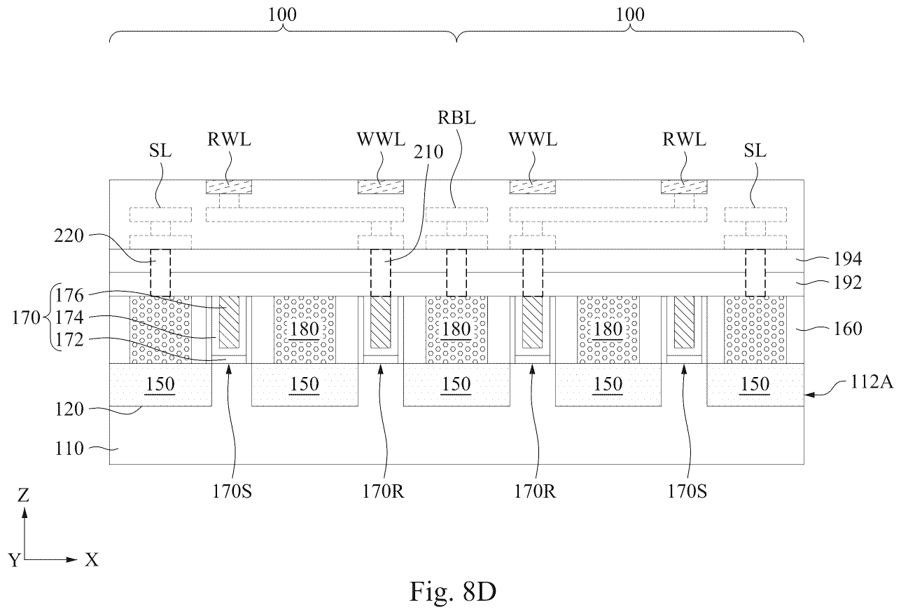

Reference is made to FIGS. 8A-8D. A multi-layered interconnect (MLI) structure 240 is formed over the gate vias 210, the source/drain vias 220, and the connection features 230 and the ILD layers 192 and 194. The MLI structure 240 may include at least one metallization layers. The number of metallization layers may vary according to design specifications of the integrated circuit structure. Only three metallization layers are illustrated in FIGS. 6A-6C for the sake of simplicity. The metallization layers may be denoted as M1-M3 in the layout in FIG. 6A, in which MI is the lowest metallization layer of the MLI structure 240. The metallization layers (e.g., M1-M3) each comprise one or more inter-metal dielectric (IMD) layers 242, one or more horizontal interconnects (e.g., metal lines) 244 respectively extending horizontally in the IMD layers. One or more vertical interconnects (e.g., metal vias) 246 may extend vertically in the IMD layers 242 and connect the horizontal interconnects (e.g., metal lines) 244 in two adjacent metallization layers to each other. The vertical interconnects (e.g., metal vias) 246 may be denoted as V1-V2 in the layout in FIG. 6A, in which V1 is between M1 and M2, and V2 is between M2 and M3. The horizontal interconnects (e.g., metal lines) 244 in M2 may extend substantially along the direction Y, and may include the read bit line RBL, the reference voltage line SL, and the write bit line WBL. The horizontal interconnects (e.g., metal lines) 244 in M3 may extend substantially along a direction X substantially perpendicular to the direction Y, and may include the write word line WWL and the read word line RWL. The metal lines of the lowest metallization layer M1 of the MLI structure 240 may be in contact with the gate vias 210 and the source/drain vias 220, thereby establishing electrical connection from the MLI structure 240 to the source/drain contacts 180 and electrical connection from the MLI structure 240 to the metal gate structures 170. In some embodiments, the ILD layer(s) 194 over the connection features 230 may space/isolate the storage gate structure 170S from the MLI structure 240, such that the storage gate structure 170S is electrically disconnected from the metallization layers of the MLI structure 240.

In some embodiments, M2 includes the write bit line WBL, the read bit line RBL, and the reference voltage line SL, which extend across plural memory cells 100 substantially along the direction X. In some embodiments, M3 includes the write word line WWL and tech read word line RWL, which extend across plural memory cells 100 substantially along the direction Y. In some embodiments, a routing direction of the horizontal interconnects (e.g., metal lines) 244 in one metallization layer is different from or perpendicular to a routing direction of the horizontal interconnects (e.g., metal lines) 244 in a next metallization layer. For example, as shown in FIG. 8A and 8D. the horizontal interconnects (e.g., metal lines) 244 in M1 extends substantially along the direction Y, the horizontal interconnects (e.g., metal lines) in M2 extends substantially along the direction X, and the horizontal interconnects (e.g., metal lines) in M3 extends substantially along the direction Y.

In the layouts of FIGS. 2A, 4A, 5A, 6A, 7A, 8A, and 8B, the two memory cells 100 are arranged substantially along the direction X, and the two memory cells 100 are mirror symmetric to each other with respect to a border therebetween. The write access transistors MW of the two memory cells 100 may share a write bit line WBL, and also share a source/drain contact 180 and a source drain region 150 electrically connected to the write bit line WBL. The read access transistors MR of the two memory cells 100 may share a read bit line RBL, and also share a source/drain contact 180 and a source drain region 150 electrically connected to the read bit line RBL. With the configuration, the plural memory cells 100 can be arrayed.

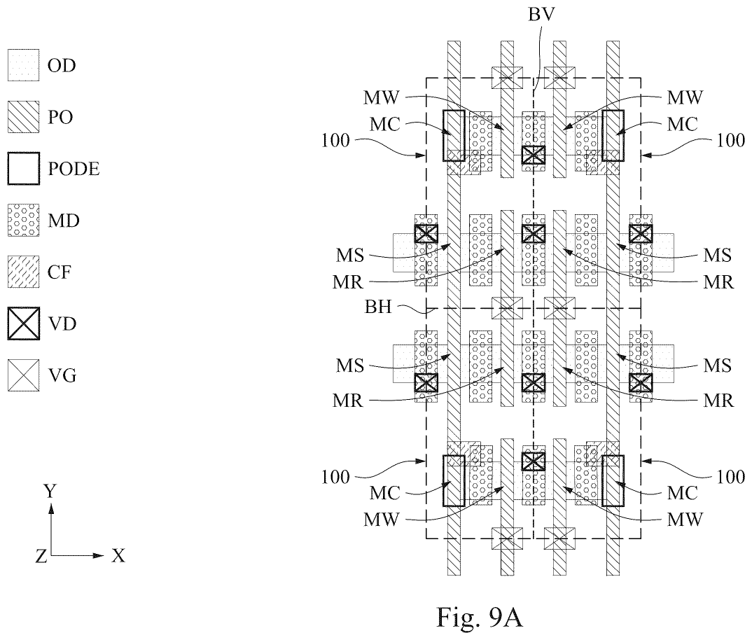

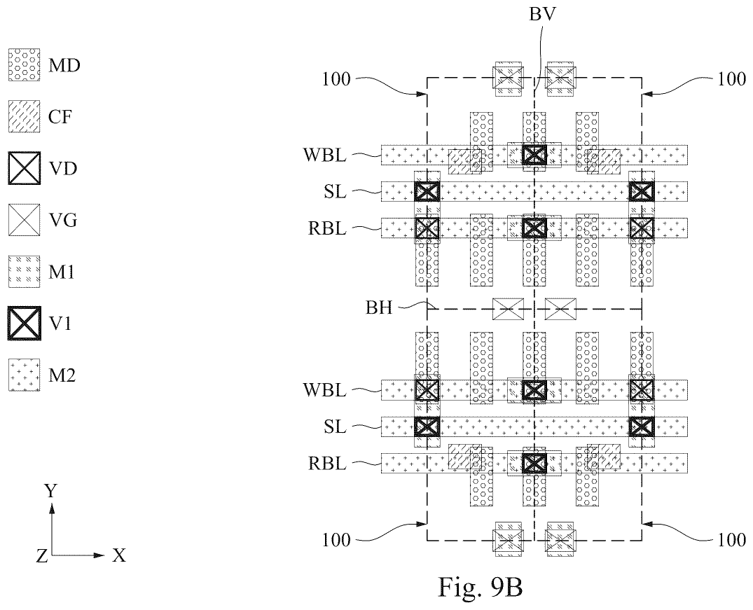

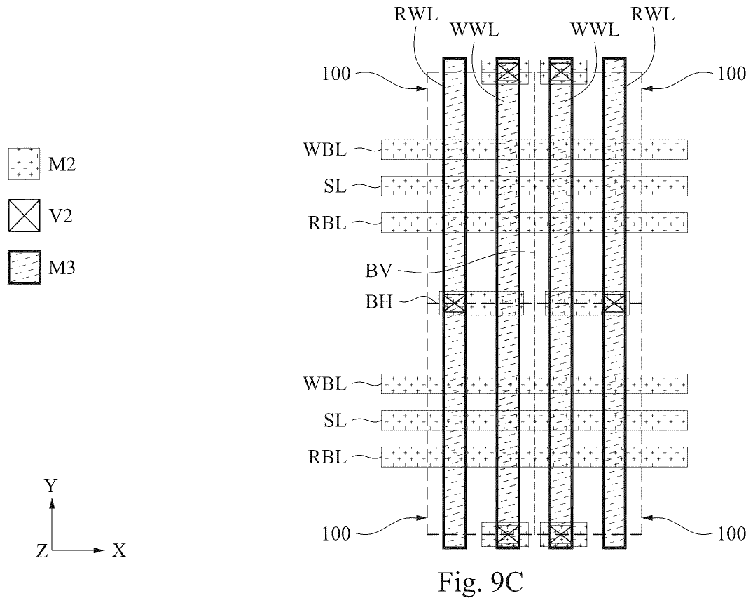

FIGS. 9A-9C are layouts of an integrated circuit device including plural memory cells according to some embodiments of the present disclosure. Details of the present embodiments are similar to those illustrated in FIGS. 2A-8C, except that a memory array including four memory cells 100 are illustrated in the present embodiments. The four memory cells 100 are arrayed along the directions X and Y. The pattern of the four memory cells 100 including the transistors MC, MS, MW, MR are arranged in a symmetric manner. For example, a first row of the memory cells 100 is substantially symmetric with a second row of the memory cells 100 with respect to a border BH therebetween, and a first column of the memory cells 100 is substantially symmetric with a second column of the memory cells 100 with respect to a border BV therebetween. The write access transistors MW of the two memory cells 100 in the same row may share a write bit line WBL, and the read access transistors MR of the two memory cells 100 in the same row may share a read bit line RBL. The write access transistors MW of the two memory cells 100 in the same column may share a write word line WWL, and the read access transistors MR of the two memory cells 100 in the same column may share a read word line RWL. Other details of the present disclosure are similar to those illustrated above, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a dummy transistor is added to a memory cell, the dummy transistor is coupled between the storage node and a floating node and active in response to a voltage at the storage node, thereby increasing a parasitic capacitance on the storage node and improve a retention time, which is beneficial for saving energy for refresh operation. Another advantage is that the dummy transistor can use the polysilicon on OD edge (“PODE”) regions, and thus does not increase a cell region of the memory cell.

In some embodiments of the present disclosure, a memory cell includes a write access transistor, a storage transistor, a read access transistor, and a dummy transistor. The write access transistor is coupled between a storage node and a write bit line. A gate of the write access transistor is coupled to a write word line. The storage transistor is coupled between a common node and a ground line. A gate of the storage transistor is coupled to the storage node. The read access transistor is coupled between the common node and a read bit line. A gate of the read access transistor is coupled to a read word line. A gate of the dummy transistor is coupled to the storage node, and a source/drain region of the dummy transistor is coupled to the storage node.

In some embodiments of the present disclosure, a memory cell includes a semiconductor substrate, a storage gate structure, a write access gate structure, a read access gate structure, and an interconnect structure. The semiconductor substrate comprises a first active region and a second active region. A longitudinal direction of the first active region is substantially parallel with a longitudinal direction of the second active region. A storage gate structure extends across the first active region and the second active region in a top view. The first active region does not extend beyond a sidewall of the storage gate structure, and the second active region extend beyond the sidewall of the storage gate structure in the top view. The write access gate structure extends across the first active region in the top view. The read access gate structure extends across the second active region in the top view. The interconnect structure is over the storage gate structure, the write access gate structure, and the read access gate structure. The interconnect structure comprises a write word line electrically coupled with the write access gate structure and a read word line electrically coupled with the read access gate structure.

In some embodiments of the present disclosure, a method includes forming a first active region and a second active region over a semiconductor substrate, wherein a longitudinal direction of the first active region is substantially parallel with a longitudinal direction of the second active region, and the second active region extend beyond a side of the first active region in a top view; forming a storage gate structure over the first active region and the second active region, a write access gate structure over the first active region, and a read access gate structure over the second active region, wherein the storage gate structure overlaps the side of the first active region; and forming an interconnect structure over the storage gate structure, the write access gate structure, and the read access gate structure, wherein the interconnect structure comprises a write word line electrically coupled with the write access gate structure and a read word line electrically coupled with the read access gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
a write access transistor coupled between a storage node and a write bit line, wherein a gate of the write access transistor is coupled to a write word line;
a storage transistor coupled between a common node and a ground line, wherein a gate of the storage transistor is coupled to the storage node;
a read access transistor coupled between the common node and a read bit line, wherein a gate of the read access transistor is coupled to a read word line; and
a dummy transistor, wherein a gate of the dummy transistor is coupled to the storage node, and a source/drain region of the dummy transistor is coupled to the storage node.

2. The memory cell of claim 1, wherein the dummy transistor comprising:
an active region, wherein the gate of the dummy transistor comprises a gate structure overlapping a side of the active region.

3. The memory cell of claim 1, wherein the gate of the storage transistor and the gate of the dummy transistor share a gate structure coupled to the storage node.

4. The memory cell of claim 1, wherein the source/drain region of the dummy transistor is shared with the write access transistor.

5. The memory cell of claim 1, wherein the gate of the read access transistor comprises a first gate structure, the gate of the storage transistor comprises a second gate structure aligned with the first gate structure substantially along a longitudinal direction of the first gate structure in a top view.

6. The memory cell of claim 1, wherein the read access transistor and the storage transistor share a source/drain region.

7. A memory cell, comprising:
a semiconductor substrate comprising a first active region and a second active region, wherein a longitudinal direction of the first active region is substantially parallel with a longitudinal direction of the second active region;
a storage gate structure extending across the first active region and the second active region in a top view, wherein the first active region does not extend beyond a sidewall of the storage gate structure, and the second active region extends beyond the sidewall of the storage gate structure in the top view;
a write access gate structure extending across the first active region in the top view;
a read access gate structure extending across the second active region in the top view; and
an interconnect structure over the storage gate structure, the write access gate structure, and the read access gate structure, wherein the interconnect structure comprises a write word line electrically coupled with the write access gate structure and a read word line electrically coupled with the read access gate structure.

8. The memory cell of claim 7, wherein the first active region has a first side extending substantially along the longitudinal direction of the first active region and a second side adjoining the first side of the first active region, and the second side of the first active region is directly below the storage gate structure.

9. The memory cell of claim 8, further comprising:
an isolation structure surrounding the first active region and the second active region, wherein the second side of the first active region is in contact with the isolation structure.

10. The memory cell of claim 7, wherein the first active region has a first side extending substantially along the longitudinal direction of the first active region and a second side adjoining the first side of the first active region, and the storage gate structure is in contact with the second side of the first active region in the top view.

11. The memory cell of claim 7, wherein the first active region has a first side extending substantially along the longitudinal direction of the first active region and a second side adjoining the first side of the first active region, and the second active region extends beyond the first side of the first active region in the top view.

12. The memory cell of claim 7, further comprising:
an interlayer dielectric layer isolating the storage gate structure from the interconnect structure.

13. The memory cell of claim 7, wherein the read access gate structure is substantially aligned with the write access gate structure along a gate direction crossing the longitudinal direction of the first active region in the top view.

14. The memory cell of claim 7, further comprising:
an isolation structure surrounding the first active region and the second active region, wherein a bottom surface of the storage gate structure has a first portion over the first active region and a second portion in contact with the isolation structure when viewing along a gate direction crossing the longitudinal direction of the first active region.

15. The memory cell of claim 7, wherein the first active region comprises a source/drain region between the storage gate structure and the write access gate structure, and the source/drain region of the first active region is electrically coupled to the storage gate structure.

16. The memory cell of claim 7, wherein the interconnect structure comprises:
a write bit line electrically coupled with a source/drain region of the first active region on a side of the write access gate structure facing away from the storage gate structure; and
a read bit line electrically coupled with a source/drain region of the second active region on a side of the read access gate structure facing away from the storage gate structure.

17. The memory cell of claim 7, wherein the interconnect structure comprises:
a ground line electrically coupled with a source/drain region of the second active region on a side of the storage gate structure facing away from the read access gate structure.

18. A method, comprising:
forming a first active region and a second active region over a semiconductor substrate, wherein a longitudinal direction of the first active region is substantially parallel with a longitudinal direction of the second active region, and the second active region extends beyond a side of the first active region in a top view;
forming a storage gate structure over the first active region and the second active region, a write access gate structure over the first active region, and a read access gate structure over the second active region, wherein the storage gate structure overlaps the side of the first active region; and
forming an interconnect structure over the storage gate structure, the write access gate structure, and the read access gate structure, wherein the interconnect structure comprises a write word line electrically coupled with the write access gate structure and a read word line electrically coupled with the read access gate structure.

19. The method of claim 18, further comprising:
forming an isolation structure over the semiconductor substrate to surround the first active region and the second active region, wherein the isolation structure is in contact with the side of the first active region.

20. The method of claim 18, wherein forming the storage gate structure, the write access gate structure, and the read access gate structure comprises:
forming a plurality of dummy gate structures over the first active region and the second active region, wherein one of the dummy gate structures overlaps the side of the first active region; and
replacing the dummy gate structures with a gate dielectric layer and a gate metal layer.
